(19) United States
(12) Patent Application Publication
(10) Pub. No.: US 2020/0043908 A1
(43) Pub. Date: Feb. 6, 2020

(54) PACKAGE STACKED STRUCTURE, METHOD FOR FABRICATING THE SAME, AND PACKAGE STRUCTURE

(71) Applicant: Siliconware Precision Industries Co., Ltd., Taichung City (TW)

(72) Inventors: Chee-Key Chung, Taichung City (TW); Chang-Fu Lin, Taichung City (TW); Han-Hung Chen, Taichung City (TW); Jen-Chieh Hsiao, Taichung City (TW); Rung-Jeng Lin, Taichung City (TW); Kuo-Hua Yu, Taichung City (TW); Hong-Da Chang, Taichung City (TW)

(21) Appl. No.: 16/164,416

(22) Filed: Oct. 18, 2018

(30) Foreign Application Priority Data
Aug. 1, 2018 (TW) 107126730
Sep. 14, 2018 (TW) 107132430

(51) Int. Cl. H01L 25/00; H01L 23/538; H01L 21/48; H01L 25/10; H01L 21/683; H01L 21/56; H01L 23/00

(52) U.S. Cl. CPC H01L 25/50; H01L 23/5389; H01L 21/4857; H01L 21/4853; H01L 25/105; H01L 21/6835; H01L 2224/16227; H01L 24/16; H01L 2225/1035; H01L 2225/1041; H01L 2225/1058; H01L 2221/68345; H01L 2221/68359; H01L 21/56

(57) ABSTRACT

A package stacked structure and a method for fabricating the same are provided. The method includes providing a wiring structure disposed with a carrier and a carrier structure provided with an electronic component. The wiring structure is bonded to the carrier structure via a plurality of conductive elements. An encapsulating layer is formed between the wiring structure and the carrier structure and encapsulates the conductive elements and the electronic component. The carrier is then removed. With the arrangement of the carrier, the structural strength of the wiring structure is improved, and warpage of the wiring structure is prevented before stacking the wiring structure onto the carrier structure.

### BACKGROUND

### 1. Technical Field

The present disclosure relates to semiconductor fabricating processes, and, more particularly, to a package stacked structure, a method for fabricating the same, and a package structure.

### 2. Description of Related Art

With the evolution of semiconductor package technology, various kinds of packaging techniques for semiconductor devices have been developed. In order to improve electrical functionalities and save package space, a packaging technique called “Package on Package” (POP) was created which involves stacking of a plurality of package structures one on top of the other. Such a packaging method heterogeneously integrates electronic components of different functionalities (e.g., a memory, a CPU, a graphics processor, an image application processor, etc.) to form a “System in Package” (SiP). System integration is achieved by stacking and is particularly suited for various compact and lightweight electronic products.

FIG. 1 is a cross-sectional schematic diagram of a traditional package stacked structure 1. The package stacked structure 1 includes a first semiconductor element 10, a first package substrate 11, a second package substrate 12, a plurality of solder balls 13, second semiconductor elements 14 and an encapsulant 15. The first package substrate 11 includes a core layer 110 and a plurality of wiring layers 111. The second package substrate 12 also includes a core layer 120 and a plurality of wiring layers 121. The first semiconductor element 10 is disposed on the first package substrate 11 in a flip-chip manner. Similarly, the second semiconductor elements 14 are disposed on the second package substrate 12 in a flip-chip manner. The solder balls 13 are used for connecting and electrically coupling the first package substrate 11 and the second package substrate 12. The encapsulant 15 encapsulates the solder balls 13 and the first semiconductor element 10. Optionally, an underfill 16 can be formed between the first semiconductor element 10 and the first package substrate 11.

However, in the conventional package stacked structure 1, both the first package substrate 11 and the second package substrate 12 include core layers 110 and 120, thus the cost of manufacturing is high. Moreover, as the thickness H of the package stacked structure 1 is approximately 620 μm, which does not meet the demands for compact and lightweight devices.

Therefore, there is a need for a solution that addresses the aforementioned issues in the prior art.

### SUMMARY

In view of the aforementioned shortcomings of the prior art, the present disclosure provides a package stacked structure, which may include: a plurality of conductive elements; a carrier structure including a first side having at least one electronic component disposed thereon; and a wiring structure including a first side having a carrier disposed thereon and a second side bonded to the first side of the carrier structure via the conductive elements.

In an embodiment, the package stacked structure further includes an encapsulating layer formed between the wiring structure and the carrier structure and encapsulating the conductive elements and the electronic component.

The present disclosure further provides a method for fabricating a package stacked structure, which may include: providing a wiring structure disposed with a carrier and a carrier structure including a first side having at least one electronic component disposed thereon; bonding the wiring structure to the first side of the carrier structure via a plurality of conductive elements; forming between the wiring structure and the carrier structure an encapsulating layer that encapsulates the conductive elements and the electronic component; and removing the carrier.

In an embodiment, the carrier is a silicon wafer and bonded to a dielectric material of the wiring structure. In another embodiment, the carrier is removed by grinding.

In an embodiment, the wiring structure is a redistribution-layer wiring structure.

In an embodiment, the wiring structure includes a first surface bonded to the carrier and a second surface opposing the first surface and having a plurality of stacked contacts provided thereon and bonded to the conductive elements.

In an embodiment, the carrier is glass and bonded to a dielectric material of the wiring structure through a bonding layer. In another embodiment, the carrier and bonding layer can be removed by stripping.

In an embodiment, the conductive elements are solder balls, metal pillars, or insulating bumps with metal claddings.

In an embodiment, the wiring structure is singulated.

In an embodiment, the wiring structure is an array panel.

In an embodiment, the carrier structure is singulated.

In an embodiment, the carrier structure is an array panel.

The present disclosure further provides a package structure, which may include: a wiring structure including a first side and a second side opposing the first side; a carrier disposed on the first side of the wiring structure; and a plurality of conductive elements disposed on the second side of the wiring structure and electrically connected with the wiring structure.

In an embodiment, the carrier is a silicon wafer and bonded to a dielectric material of the wiring structure.

In an embodiment, the wiring structure includes a first surface bonded to the carrier and a second surface opposing the first surface and bonded to the conductive element.

In an embodiment, the carrier is glass and bonded to a dielectric material of the wiring structure through a bonding layer.

In an embodiment, the wiring structure is a redistribution-layer wiring structure.

In an embodiment, the wiring structure includes a first surface bonded to the conductive element and a second surface opposing the first surface and bonded to the carrier.

In an embodiment, the conductive element is solder ball, metal pillar, or insulating bump with metal cladding.

In an embodiment, the carrier structure is singulated.

In an embodiment, the carrier structure is an array panel.

As can be understood from the above, the package stacked structure, a method of fabricating the same and a package structure in accordance with the present disclosure enhance the structural strength of the wiring structure by essentially providing carriers. Compared to the prior art, the wiring structure can be configured to be coreless, this allows the overall thickness of the package stacked structure to be reduced, at the same time, preventing warpage from occurring in the wiring structure before stacking the wiring structure onto the carrier structure.

### BRIEF DESCRIPTION OF THE DRAWINGS

FIG. 1 is a cross-sectional schematic diagram of a traditional package stacked structure.

FIGS. 2A to 2F are cross-sectional schematic diagrams depicting a method for fabricating a package stacked structure in accordance with a first embodiment of the present disclosure.

FIGS. 2A′ and 2A″ are partially enlarged view of FIG. 2A in accordance with different embodiments of the present disclosure.

FIG. 2B′ is a partially enlarged view of FIG. 2B in accordance with another embodiment of the present disclosure.

FIGS. 2C′ to 2E′ are another embodiment of FIGS. 2C to 2E.

FIGS. 3A to 3E are cross-sectional schematic diagrams depicting a method for fabricating a package stacked structure in accordance with a second embodiment of the present disclosure.

FIGS. 3B′ and 3B″ are cross-sectional schematic diagrams of the structure of FIG. 3B in accordance with different embodiments of the present disclosure.

FIGS. 3C′ to 3D′ are subsequent process of FIG. 3B′.

FIGS. 4A to 4D are cross-sectional schematic diagrams depicting a method for fabricating a package stacked structure in accordance with a third embodiment of the present disclosure.

FIGS. 5A to 5C are cross-sectional schematic diagrams depicting a method for fabricating a package stacked structure in accordance with a fourth embodiment of the present disclosure.

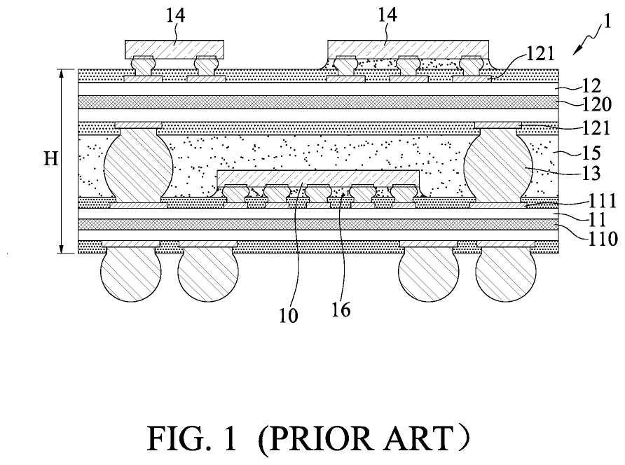

### DETAILED DESCRIPTION OF THE EMBODIMENTS

The technical content of present disclosure is described by the following specific embodiments. One of ordinary skill in the art can readily understand the advantages and effects of the present disclosure upon reading the disclosure of this specification. The present disclosure may also be practiced or applied with other different implementations. Based on different contexts and applications, the various details in this specification can be modified and changed without departing from the spirit of the present disclosure.

It should be noted that the structures, ratios, sizes shown in the drawings appended to this specification are to be construed in conjunction with the disclosure of this specification in order to facilitate understanding of those skilled in the art. They are not meant, in any ways, to limit the implementations of the present disclosure, and therefore have no substantial technical meaning. Without affecting the effects created and objectives achieved by the present disclosure, any modifications, changes or adjustments to the structures, ratio relationships or sizes, are to be construed as fall within the range covered by the technical contents disclosed herein. Meanwhile, terms, such as “first”, “second”, “above”, “one”, “a”, “an”, and the like, are for illustrative purposes only, and are not meant to limit the range implementable by the present disclosure. Any changes or adjustments made to their relative relationships, without modifying the substantial technical contents, are also to be construed as within the range implementable by the present disclosure.

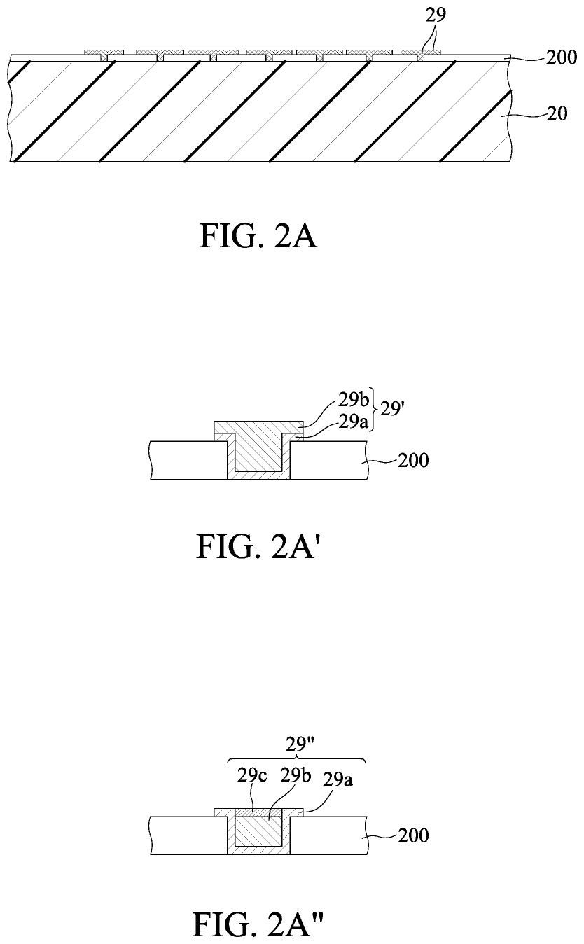

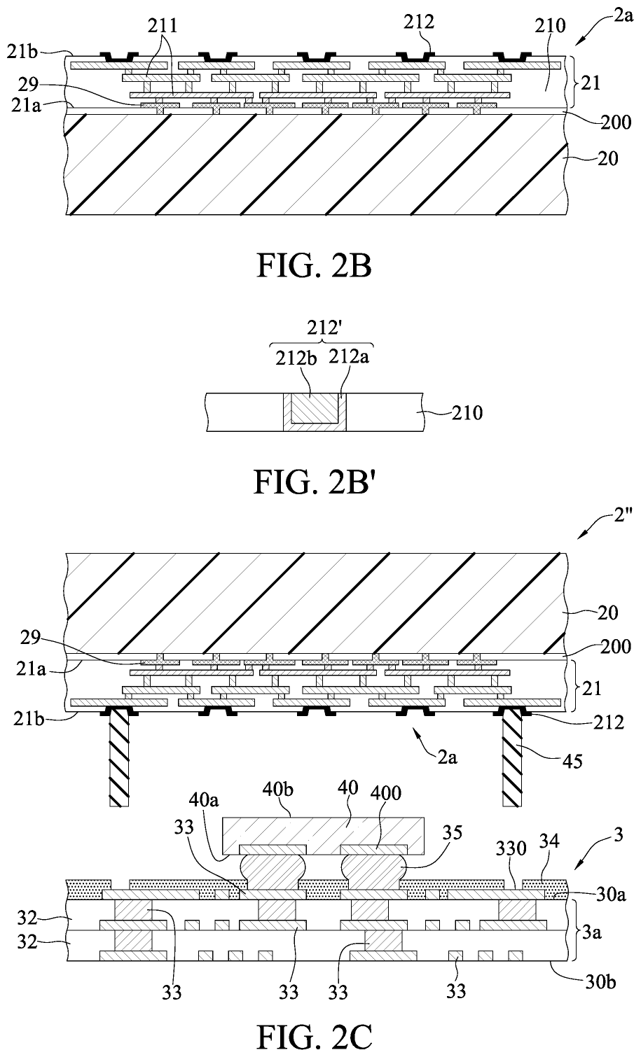

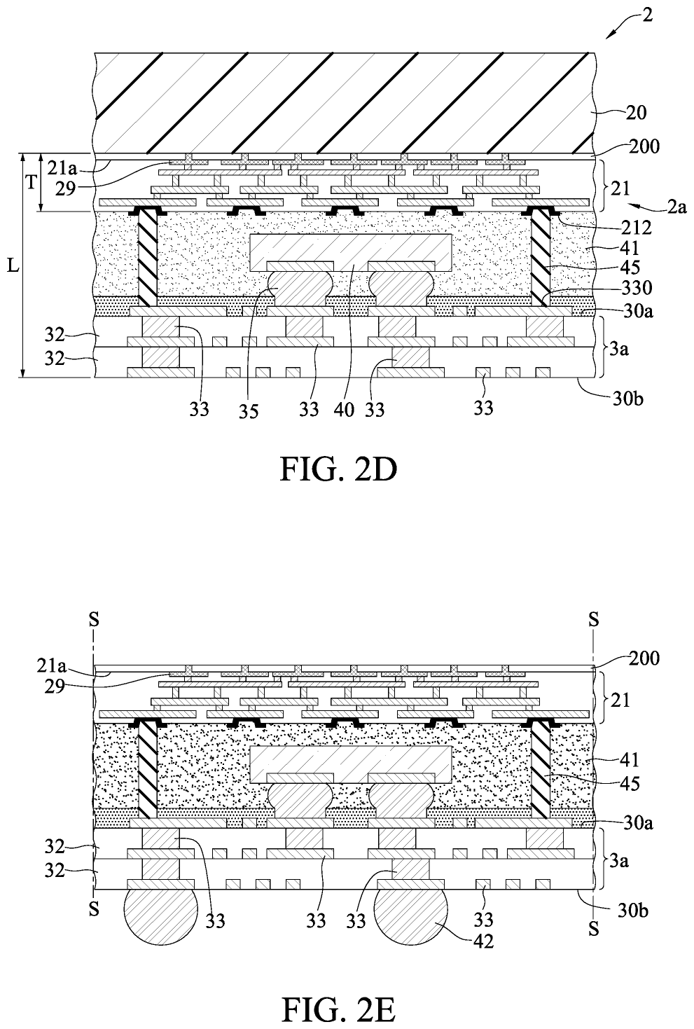

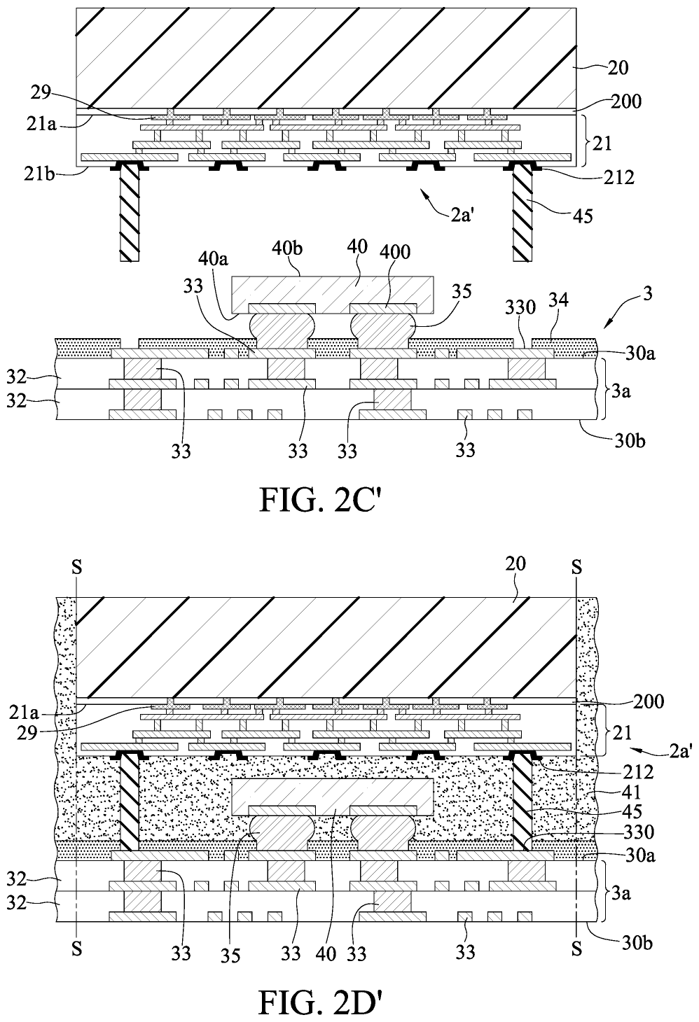

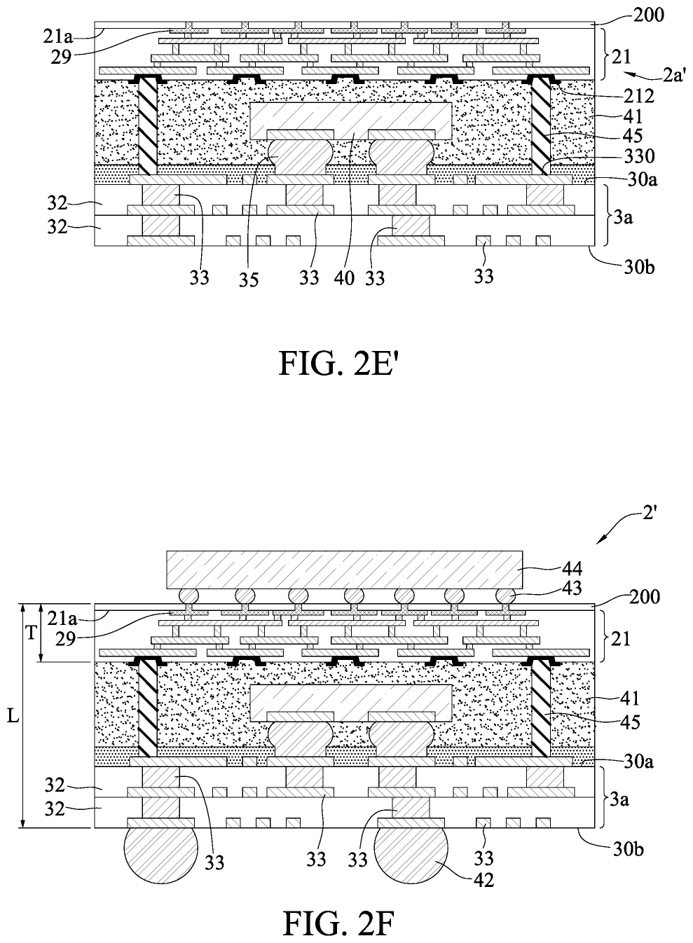

Referring to FIGS. 2A to 2F, cross-sectional schematic diagrams depicting a method for fabricating a package stacked structure 2, 2′ in accordance with a first embodiment of the present disclosure are shown.

As shown in FIG. 2A, a dielectric layer 200 is formed on a first carrier 20, and a plurality of metal structures 29 are formed on the dielectric layer 200.

In an embodiment, the first carrier 20 is a semiconductor board, such as an array panel of temporary silicon (Si) wafer.

As shown in FIG. 2A′, the metal structures 29 each includes a plurality of metal layers. In an embodiment, the dielectric layer 200 having a plurality of openings are first formed on the first carrier 20, then a first metal layer 29a is formed on the dielectric layer 200 and the openings, and then a second metal layer 29b is further formed on portions of the first metal layer 29a. Thereafter, the portions of the first metal layer 29a not covered by the second metal layer 29b are removed, resulting in metal structures 29′ composed of the stacked first and second metal layers 29a, 29b. In another embodiment, as shown in FIG. 2A″, after the portions of the first metal layer 29a not covered by the second metal layer 29b are removed, a third metal layer 29c is further formed on the second metal layer 29b, thereby forming metal structures 29″ composed of the stacked first, second and third metal layers 29a, 29b, 29c.

As shown in FIG. 2B, a wire portion 21 is then formed on the dielectric layer 200 and the metal structures 29, such that the wire portion 21, the dielectric layer 200 and the metal structures 29 form an array panel of wire structure 2a.

In an embodiment, the wire portion 21 includes a first surface 21a and a second surface 21b opposing to the first surface 21a, and is joined with the dielectric layer 200 and the metal structures 29 at the first surface 21a. The wire portion 21 further includes a dielectric body 210 and wiring layers 211 bonded to the dielectric body 210 and electrically connected with the metal structures 29. The outermost wiring layer 211 can be formed with under bump metallurgy (UBM) thereon to be used as stacked contacts 212. Alternatively, the outermost wiring layer 211 can be formed with bumps on trace (BOT) thereon as stacked contacts 212′, which can be seen as individually made up of a conductive layer 212a and a metal bump 212b in FIG. 2B′.

In an embodiment, the wire portion 21 can be formed using a so-called “fan-out redistribution layer” (RDL) technique. In the conventional wafer process, the dielectric layer associated with forming the wiring layers is usually formed with silicon nitride or silicon oxide using a chemical vapor deposition (CVD) process, which is rather expensive, so a non-wafer manufacturing technique can be used for forming the wirings. That is, a less expensive polymer dielectric layer such as polyimide (PI) or polybenzoxazole (PBO) is coated between the wiring layers to achieve insulation.

As shown in FIG. 2C, conductive elements 45 are bonded onto the stacked contacts 212 of the array panel of wiring structure 2a to form a package structure 2″. A package assembly 3 is also provided, which includes an array panel of carrier structure 3a and an electronic component 40 bonded to the carrier structure 3a. The carrier structure 3a is defined with a first side 30a and a second side 3b opposing the first side 30a.

In an embodiment, the carrier structure 3a is a wiring structure with or without a core layer, such as a package substrate with a fan-out RDL wiring configuration. In another embodiment, the carrier structure 3a includes a plurality of insulating layers 32 and routing layers 33 on the insulating layers 32. In yet another embodiment, the insulating layers 32 can be made up of a prepreg, a molding compound, or a photosensitive dielectric layer, but is not limited as such. An insulating protective layer 34 (e.g., a solder-resist layer) can be further formed on the first side 30a of the carrier structure 3a, such that the surface of the routing layer 33 is partially exposed from the insulating protective layer 34 and used as electrical connection pads 330. It can be appreciated that the carrier structure 3a can also be formed of other types of board materials for carrying chips, such as a leadframe, a wafer, a carrier board for metal routing, etc., and the present disclosure is not limited to these.

In an embodiment, the electronic component 40 can be an active component, a passive component, or a combination of both, wherein the active component can be, for example, a semiconductor chip, and the passive component is, for example, a resistor, a capacitor, or an inductor. In another embodiment, the electronic component 40 is a semiconductor chip including an active face 40a and a non-active face 40b opposite to the active face 40a. The active face 40a is provided with a plurality of electrode pads 400. The electronic component 40 is attached to a plurality of conductive bumps 35 on the first side 30a of the carrier structure 3a in a flip-chip manner via the electrode pads 400 and is electrically connected to portions of the routing layer 33.

In an embodiment, the electronic component 40 can be electrically connected to the carrier structure 3a via a plurality of solder wires (not shown) by the wire bonding technique. In another embodiment, the electronic component 40 can be made to be in direct contact with the wirings of the carrier structure 3a, for example, the electronic component 40 can be embedded in the carrier structure 3a.

It can be appreciated that there are various ways of electrically connecting the electronic component 40 and the carrier structure 3a, and the present disclosure is not limited to the above.

As shown in FIG. 2D, the array panel of wiring structure 2a is bonded to the electrical connection pads 330 of the array panel of carrier structure 3a via the conductive elements 45. In an embodiment, an encapsulating layer 41 is formed between the array panel of wiring structure 2a and the array panel of carrier structure 3a, and encapsulates the electronic component 40, the conductive elements 45, and the conductive bumps 35.

In an embodiment, the conductive elements 45 can be insulating bumps with metal claddings, metal pillars (e.g., Cu pillars), solder balls, balls with Cu cores, etc. It can come in various shapes, such as cylindrical, elliptical cylindrical or polygonal cylindrical.

In another embodiment, the conductive elements 45 can be first formed on the carrier structure 3a before being bonded to the wiring structure 2a. In another embodiment, another type of conductive elements can also be formed on the carrier structure 3a, which are then bonded to the conductive elements 45 of the package stacked structure 2″.

In an embodiment, the encapsulating layer 41 is made of an insulating material, such as an epoxy resin encapsulant, but the present disclosure is not limited as such.

In another embodiment, before the wiring structure 2a is bonded to the carrier structure 3a, an underfill (not shown) is formed between the electronic component 40 and the carrier structure 3a and encapsulates the conductive bumps 35.

As shown in FIG. 2E, the first carrier 20 is removed by a grinding, for example, to expose the metal structures 29 and the dielectric layer 200. A plurality of external connecting elements 42 that are electrically connected with the routing layers 33 are also formed on the second side 30b of the carrier structure 3a.

In an embodiment, the external connecting elements 42 can be solder balls or other metal bodies for connecting to an electronic device (e.g., a circuit board) (not shown) in the subsequent process.

As shown in FIG. 2F, singulation is performed by dicing along cutting paths S shown in FIG. 2E to obtain the package stacked structure 2′, which can be connected to another electronic component 44 (e.g., a memory chip) by bonding the metal structures 29 with conductive materials (e.g., solder materials 43) on the electronic component 44.

In another embodiment, as shown in FIG. 2C′, a pre-dicing process is performed on the array panel of wiring structure 2a, to obtain a plurality of singulated wiring structures 2a′; then the singulated wiring structures 2a′ are stacked on the array panel of carrier structure 3a via the conductive elements 45. Then, as shown in FIG. 2D′, an encapsulating layer 41 is formed between the singulated wiring structures 2a′ and the array panel of carrier structure 3a and encapsulates the electronic component 40, the conductive elements 45, the conductive bumps 35 and the singulated wiring structures 2a′. Then, as shown in FIG. 2E′, the first carrier 20 is removed by a grinding process, and then a singulation process is performed along cutting paths S shown in FIG. 2D′, for example, to obtain the package stacked structure 2′ shown in FIG. 2F.

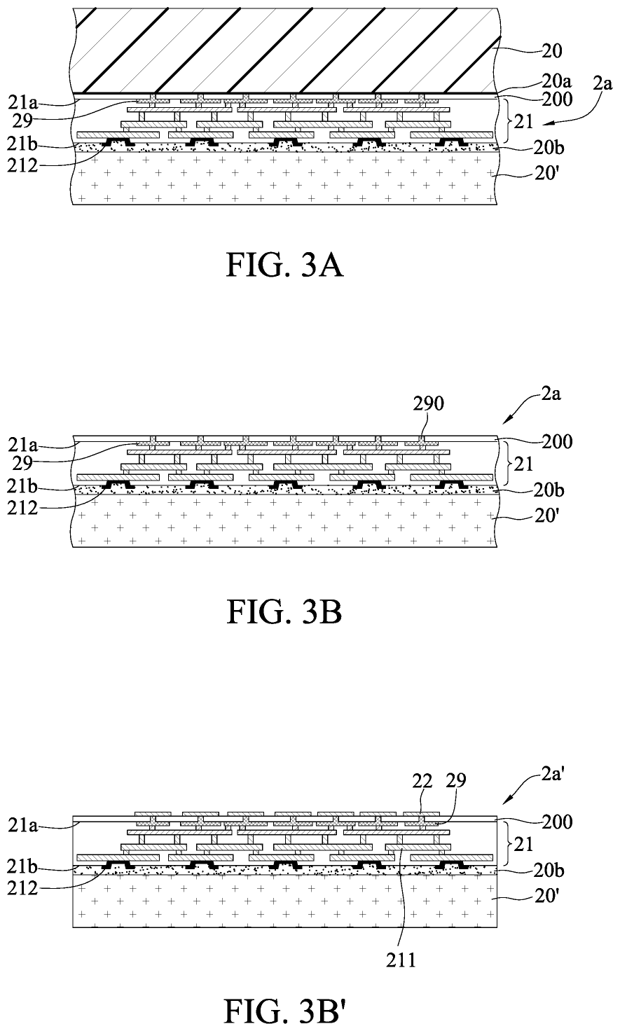

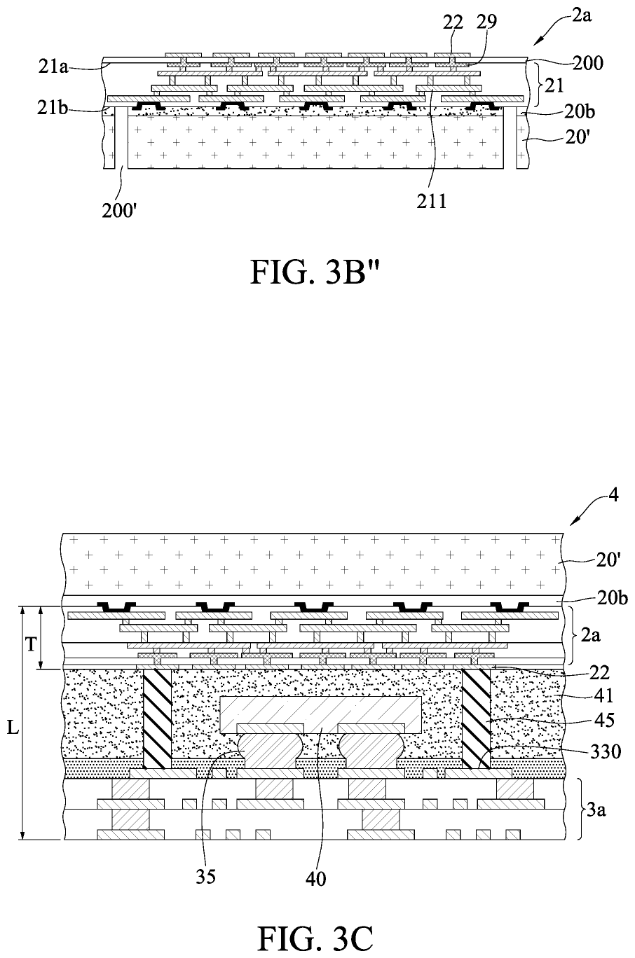

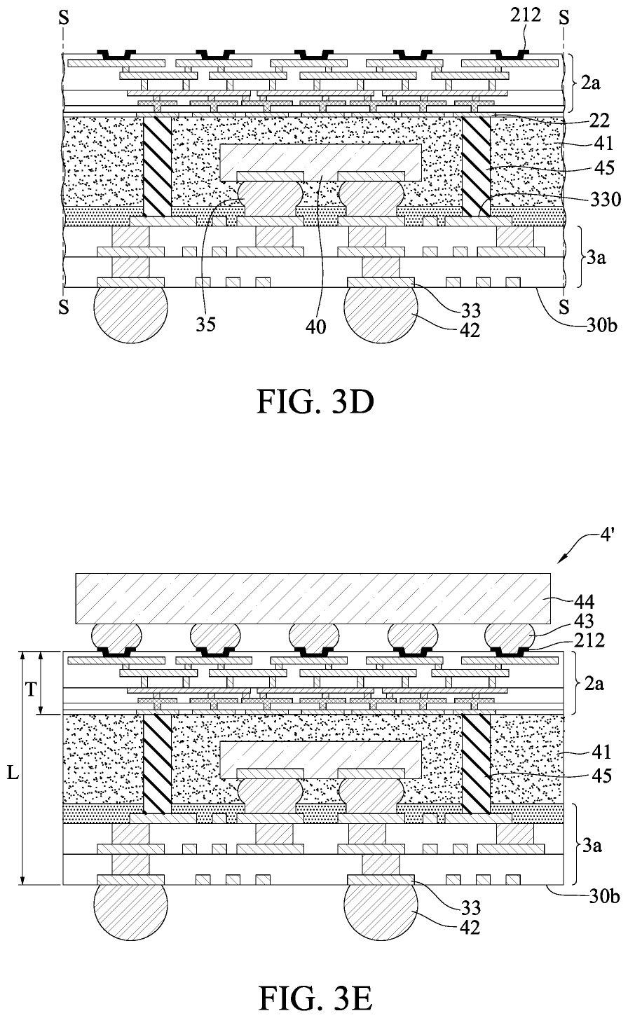

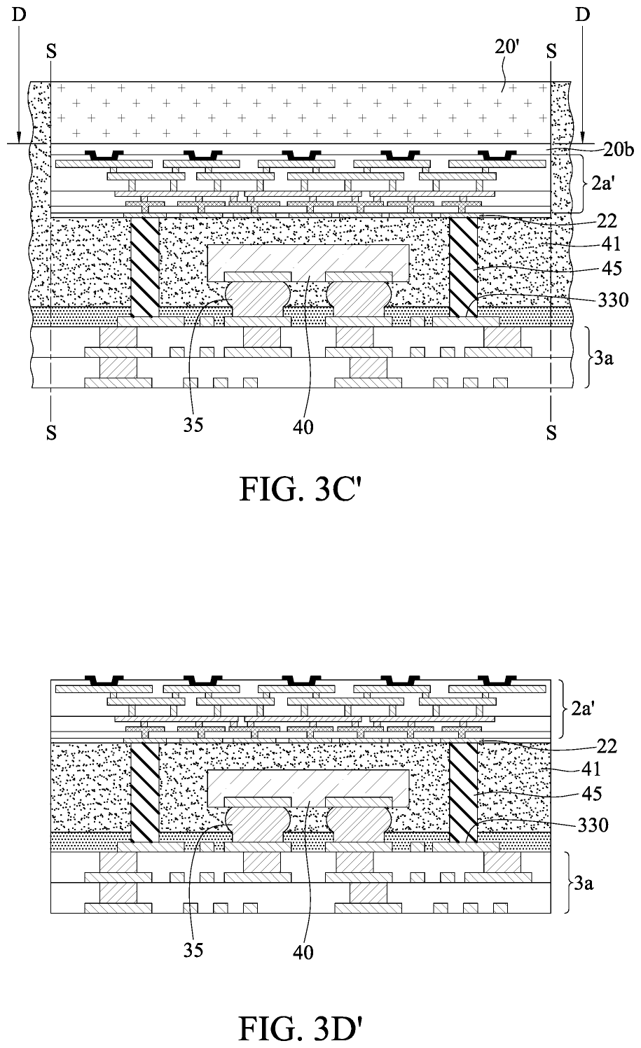

Referring now to FIGS. 3A to 3E, cross-sectional schematic diagrams depicting a method for fabricating a package stacked structure 4, 4′ subsequent to the step in FIG. 2B in accordance with a second embodiment of the present disclosure are shown. The second embodiment differs from the first embodiment only in the fabrication of the wiring structure. Thus, only the differences are described below to avoid repetition of the descriptions.

As shown in FIG. 3A, a first carrier 20 (e.g., glass) has a release layer 20a formed thereon, and a dielectric layer 200, metal structures 29 and stacked contacts 212 are fabricated to form a wiring structure 2a. Then, a second carrier 20′ is further formed on the second surface 21b of the wiring structure 2a.

In an embodiment, the second carrier 20′ can also be made of an array panel of glass, which is bonded to the second surface 21b of the wiring structure 2a via a bonding layer 20b (e.g., an adhesive), and the bonding layer 20b covers the stacked contacts 212.

As shown in FIG. 3B, the first carrier 20 and its release layer 20a are removed to expose the metal structures 29 and the dielectric layer 200.

In an embodiment, the metal structures 29 exposed from the surface of the dielectric layer 200 are used as stacked contacts 290.

In another embodiment, as shown in FIG. 3B′, a metal layer 22 can be electroplated on the metal structures 29, such that metal layer 22 is electrically connected with the wire layers 211 of the wiring structure 2a. In an embodiment, the metal layer 22 can be, for example, electrically contact pads or another UBM, and used as stacked contacts.

In an embodiment, pre-dicing can be performed as needed. As shown in FIG. 3B′, when the second carrier 20′ is in the form of a strip unit (e.g., a rectangular strip that can be bonded to a plurality of singulated wiring structures 2a), singulation can be performed directly to obtain a plurality of pre-fabricated assemblies (including singulated wiring structure 2a′ and a singulated second carrier 20′ bonded to the wiring structure 2a). In yet another embodiment, as shown in FIG. 3B″, when the second carrier 20′ is in the form of a wafer (e.g., a whole circular wafer sheet bonded to a plurality of wiring structures 2a), scribe lines 200′ (not extending to the wiring structure 2a) can be formed on the second carrier 20′.

As shown in FIG. 3C, subsequent to the step shown in FIG. 3B, the wiring structure 2a is bonded to the plurality of conductive elements 45 via its metal layer 22 (or stacked contacts 290), a package structure thus formed. The package structure is then bonded to the electrical connection pads 330 of the carrier structure 3a of FIG. 2C via the conductive elements 45. Then, the encapsulating layer 41 is formed between the wiring structure 2a and the carrier structure 3a and encapsulates the electronic component 40, the conductive elements 45, and the conductive bumps 35.

As shown in FIG. 3D, the second carrier 20′ and its bonding layer 20b are removed to expose the stacked contacts 212, and the plurality of external connecting elements 42 are formed on the second side 30b of the carrier structure 3a and electrically connected with the routing layers 33.

In an embodiment, the external connecting elements 42 can be, for example, solder balls or other metal bodies for connecting to an electronic device (e.g., a circuit board) (not shown) in the subsequent process.

As shown in FIG. 3E, singulation is performed by dicing along cutting paths S shown in FIG. 3D to obtain the package stacked structure 4′, which can be connected to another electronic component 44 (e.g., a memory chip) by bonding of its stacked contacts 212 with conductive materials (e.g., solder materials 43) on the electronic component 44.

In an embodiment, when the second carrier 20′ is in the form of a strip unit (as shown in FIG. 3B or 3B′), the bonding layer 20b may lose some of its adhesiveness through heating or irradiation (e.g., with a UV light) to facilitate the removal of the second carrier 20′ and the bonding layer 20b.

In another embodiment, as shown in FIG. 3C′, which shows the subsequent process of FIG. 3B′, the singulated wiring structures 2a′ are bonded to the array panel of carrier structure 3a; then a half-cut process is performed along the cutting paths D shown in FIG. 3C′ and then the second carrier 20′ and the bonding layer 20b are removed, followed by performing a singulation process along the cutting paths S shown in FIG. 3C′, to form the structure shown in FIG. 3D′.

In another embodiment, when the second carrier 20′ is in the form of a wafer glass (as shown in FIG. 3B″), the encapsulating layer 41 will be filled inside the scribe lines 200′ of the second carrier 20′. The encapsulating layer 41 in the scribe lines 200′ can thus be used as the cutting paths D, S for half-cut, removal of the second carrier 20′ and its bonding layer 20b, and singulation.

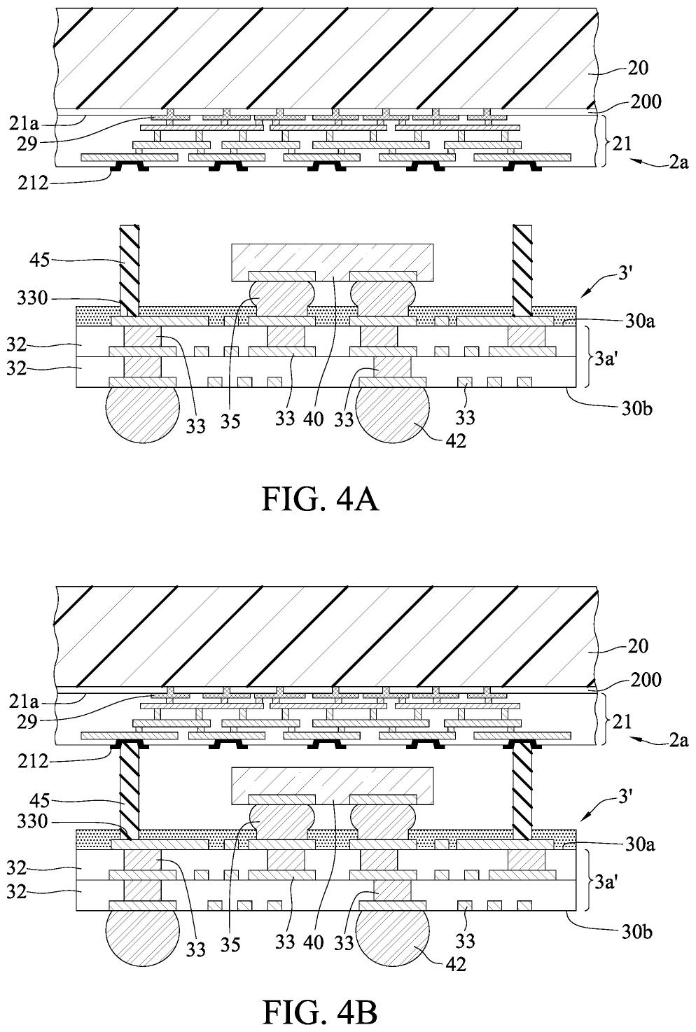

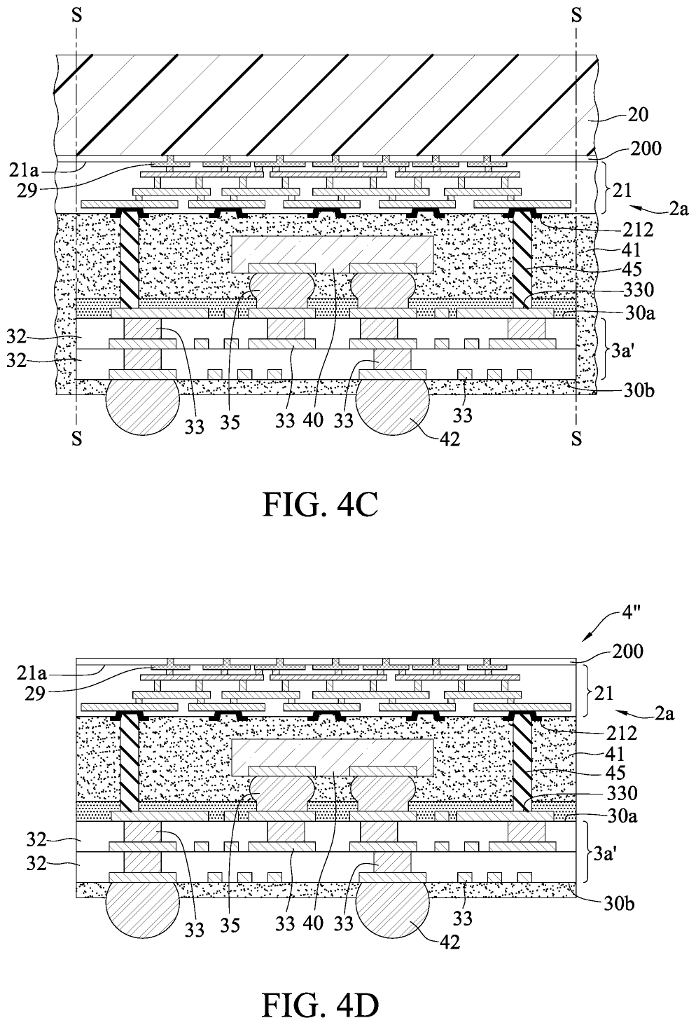

Please refer to FIGS. 4A to 4D, which are cross-sectional schematic diagrams depicting a method for fabricating a package stacked structure, following the fabrication process of FIG. 2B, in accordance with a third embodiment of the present disclosure. The third embodiment differs from the first embodiment in the fabrication process of the package assembly 3′.

As shown in FIGS. 4A and 4B, a package assembly 3′ is provided, including singulated carrier structures 3a′ and an electronic component 40 bonded to the carrier structures 3a′; the package assembly 3′ is stacked on the array panel of wiring structure 2a via a plurality of conductive elements 45, and a plurality of external connecting elements 42 are disposed on the second side 30b of the carrier structure 3a′ to electrically connect the routing layers 33 of the carrier structure 3a′.

As shown in FIG. 4C, a encapsulation layer 41 is formed on the array panel of wiring structure 2a and encapsulates the electronic component 40, the conductive elements 45, the conductive bumps 35, a portion of side surface of the external connecting elements 42, and the singulated carrier structures 3a′.

As shown in FIG. 4D, the first carrier 20 is removed by grinding, and a singulation process is performed along cutting paths S shown in FIG. 4C to obtain a package stacked structure 4″.

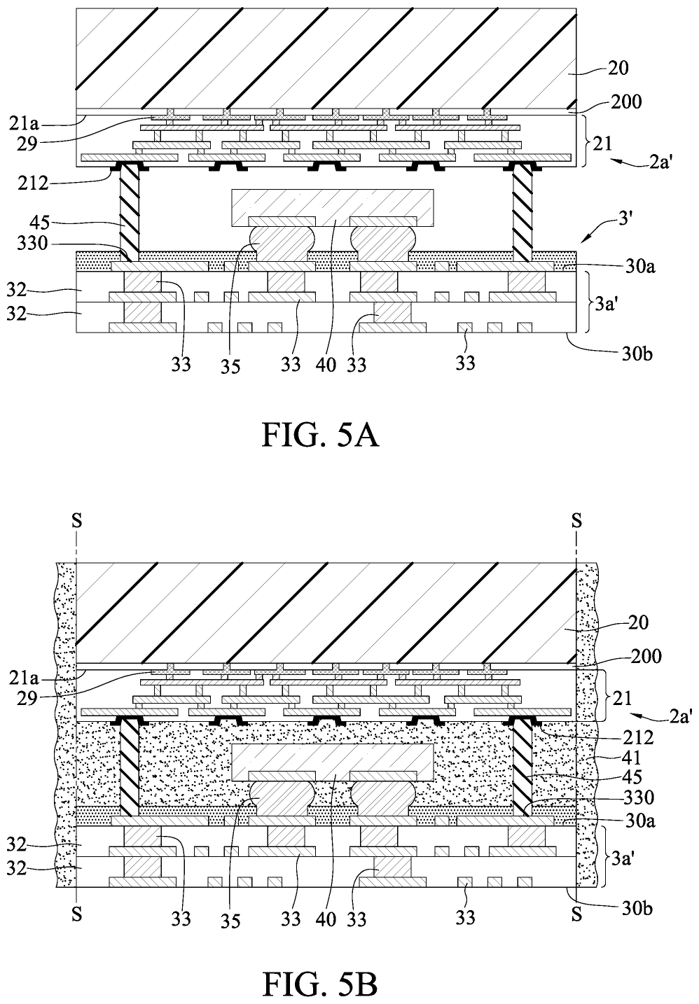

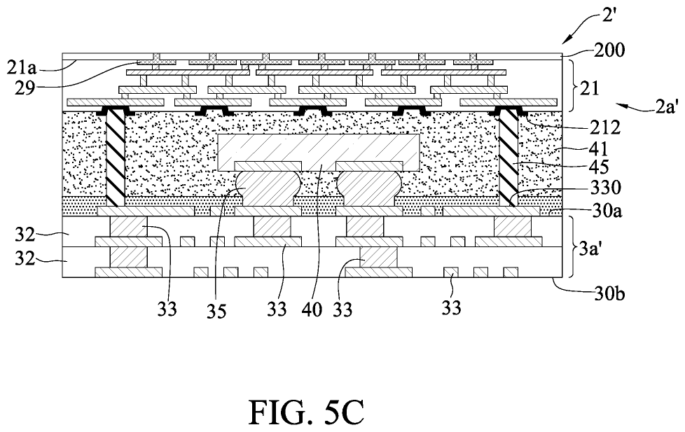

As shown in FIGS. 5A to 5C, which are cross-sectional schematic diagrams depicting a method for fabricating a package stacked structure, following the fabrication process of FIG. 2B, in accordance with a fourth embodiment of the present disclosure. The fourth embodiment differs from the first embodiment in the fabrication process of the package assembly 3′.

As shown in FIG. 5A, a package assembly 3′ is provided, including singulated carrier structures 3a′ and an electronic component 40 bonded to the carrier structure 3a′, and the package assembly 3′ is stacked on the singulated wiring structures 2a′ via the plurality of conductive elements 45.

As shown in FIG. 5B, an encapsulation layer 41 is formed between the singulated wiring structures 2a′ and the singulated carrier structures 3a′ and encapsulated the electronic component 40, the conductive elements 45, the conductive bumps 35, the singulated wiring structures 2a′ and the singulated carrier structures 3a′.

As shown in FIG. 5C, the first carrier 20 is removed by grinding, and a singulation process is performed along cutting paths S shown in FIG. 5B to obtain the package stacked structure 2′ shown in FIG. 2F.

The method for fabricating the package stacked structure according to the present disclosure reduces the thickness L of the package stacked structure 2′, 4′ through a coreless wiring structure 2a, 2a′. In addition, the structural strength of the wiring structure 2a, 2a′ is enhanced by providing carriers (i.e., the first carrier 20 and the second carrier 20′). In an embodiment, the thickness T of the wiring structure 2a, 2a′ is as small as 20 μm, and the thickness of the package stacked structure 2′, 4′, 4″ is as small as 410 μm. Compared to the prior art, the method for fabricating a package stacked structure according to the present disclosure not only significantly reduces the overall thickness of the package stacked structure 2′, 4′, 4″ but also avoids warpage of the wiring structure 2a, 2a′ before it is attached to the carrier structure 3a, 3a′ thereby meeting the demands for compact and lightweight devices.

The present disclosure further provides a package stacked structure 2, 2′, 4, 4′, 4″ which includes: a carrier structure 3a, 3a′, a wiring structure 2a, 2a′ and an encapsulating layer 41.

The carrier structure 3a, 3a′ is defined with a first side 30a and a second side 30b opposite to each other, wherein the first side 30a of the carrier structure 3a, 3a′ is disposed with at least one electronic component 40.

One side of the wiring structure 2a, 2a′ is disposed with a carrier (i.e., a first carrier 20 or a second carrier 20′), while the other side is bonded to the first side 30a of the carrier structure 3a, 3a′ via a plurality of conductive elements 45.

The encapsulating layer 41 is formed between the wiring structure 2a, 2a′ and the first side 30a of the carrier structure 3a, 3a′ and encapsulates the conductive elements 45 and the electronic component 40.

In an embodiment, the carrier (i.e., the first carrier 20) is a silicon wafer, which is directly bonded to a dielectric material (i.e., a dielectric layer 200) of the wiring structure 2a, 2a′.

In an embodiment, the wiring structure 2a, 2a′ includes a first surface 21a and a second surface 21b opposite to each other, and the first surface 21a is bonded onto the carrier (i.e., the first carrier 20), and the second surface 21b is provided with a plurality of stacked contacts 212, 212′ thereon for bonding with the conductive elements 45.

In an embodiment, the carrier (i.e., the second carrier 20′) is glass, and is directly bonded to the dielectric material (i.e., the dielectric layer 200) of the wiring structure 2a via a bonding layer 20b.

In an embodiment, the wiring structure 2a, 2a′ includes a first surface 21a and a second surface 21b opposite to each other, and the second surface 21b is bonded onto the carrier (i.e., the second carrier 20′), and the first surface 21a is provided with a plurality of stacked contacts 290 (or a metal layer 22) thereon for bonding to the conductive elements 45.

In conclusion, a package stacked structure, a method for fabricating the same and a package structure in accordance with the present disclosure reduce the thickness of the package stacked structure by providing a coreless wiring structure while enhancing the structural strength of the wiring structure with carriers arranged on the wiring structure. Therefore, the present disclosure not only significantly reduces the overall thickness of the package stacked structure, but also prevents warpage from occurring in the wiring structure.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. A package stacked structure, comprising:
a plurality of conductive elements;
a carrier structure including a first side having at least one electronic component disposed thereon; and
a wiring structure including a first side having a carrier disposed thereon and a second side bonded to the first side of the carrier structure via the conductive elements.

2. The package stacked structure of claim 1, wherein the carrier is a silicon wafer and bonded to a dielectric material of the wiring structure.

3. The package stacked structure of claim 1, wherein the wiring structure is a redistribution-layer wiring structure.

4. The package stacked structure of claim 1, wherein the wiring structure includes a first surface bonded to the carrier and a second surface opposing the first surface and having a plurality of stacked contacts provided thereon and bonded to the conductive elements.

5. The package stacked structure of claim 1, wherein the carrier is glass and bonded to a dielectric material of the wiring structure through a bonding layer.

6. The package stacked structure of claim 1, further comprising an encapsulating layer formed between the wiring structure and the carrier structure and encapsulating the conductive elements and the electronic component.

7. The package stacked structure of claim 1, wherein the conductive elements are solder balls, metal pillars, or insulating bumps with metal claddings.

8. A method for fabricating a package stacked structure, comprising:
providing a wiring structure provided with a carrier and a carrier structure including a first side having at least one electronic component disposed thereon;
bonding the wiring structure to the first side of the carrier structure via a plurality of conductive elements;
forming between the wiring structure and the carrier structure an encapsulating layer that encapsulates the conductive elements and the electronic component; and
removing the carrier.

9. The method of claim 8, wherein the conductive elements are disposed on the wiring structure and then bonded to the carrier structure.

10. The method of claim 8, wherein the conductive elements are disposed on the carrier structure and then bonded to the wiring structure.

11. The method of claim 8, wherein the carrier is a silicon wafer bonded to a dielectric material of the wiring structure.

12. The method of claim 11, wherein the carrier is removed by grinding.

13. The method of claim 8, wherein the wiring structure is a redistribution-layer wiring structure.

14. The method of claim 8, wherein the wiring structure includes a first surface bonded to the carrier and a second surface opposing the first surface and having a plurality of stacked contacts provided thereon and bonded to the conductive elements.

15. The method of claim 8, wherein the carrier is glass and bonded to a dielectric material of the wiring structure through a bonding layer.

16. The method of claim 15, wherein the carrier and bonding layer are removed by stripping.

17. The method of claim 16, wherein the wiring structure is singulated before bonded to the carrier structure, and is half-cut before the carrier is removed.

18. The method of claim 8, wherein the conductive elements are solder balls, metal pillars, or insulating bumps with metal claddings.

19. The method of claim 8, wherein the wiring structure is singulated before bonded to the carrier structure, and the carrier structure is an array panel before bonded to the wiring structure.

20. The method of claim 19, further comprising a singulation process after the carrier is removed.

21. The method of claim 8, wherein the wiring structure is an array panel before bonded to the carrier structure, and the carrier structure is an array panel before bonded to the wiring structure.

22. The method of claim 21, further comprising a singulation process after the carrier is removed.

23. The method of claim 8, wherein the wiring structure is singulated before bonded to the carrier structure, and the carrier structure is singulated before bonded to the wiring structure.

24. The method of claim 8, wherein the wiring structure is an array panel before bonded to the carrier structure, and the carrier structure is singulated before bonded to the wiring structure.

25. The method of claim 24, further comprising a singulation process after the carrier is removed.

26. A package structure, comprising:
a wiring structure including a first side and a second side opposing the first side;
a carrier disposed on the first side of the wiring structure; and
a plurality of conductive elements disposed on the second side of the wiring structure and electrically connected with the wiring structure.

27. The package structure of claim 26, wherein the wiring structure is a redistribution-layer wiring structure.

28. The package structure of claim 26, wherein the carrier is a silicon wafer and bonded to a dielectric material of the wiring structure.

29. The package structure of claim 26, wherein the carrier is glass and bonded to a dielectric material of the wiring structure through a bonding layer.

30. The package structure of claim 26, wherein the conductive element is solder ball, metal pillar, or insulating bumps with metal cladding.
